(19) United States
(12) Patent Application Publication
(10) Pub. No.: US 2008/0272766 A1
(43) Pub. Date: Nov. 6, 2008

(54) Inductive sensor

(75) Inventor: Manfred Jagiella, Notzingen (DE)

Correspondence Address: Lipsitz & McAllister, LLC, 755 MAIN STREET, MONROE, CT, 06468, US

(73) Assignee: BALLUFF GmbH, Neuhausen (DE)

(21) Appl. No.: 11/800,047

(22) Filed: May 2, 2007

(51) Int. Cl. G01R 33/16

(52) U.S. Cl. 324/201

(57) ABSTRACT

An inductive sensor is provided having a housing with a sensing face and a sensing unit arranged in the housing. The sensing unit has an oscillatory circuit with at least one inductive element. The at least one inductive element is arranged proximate to the sensing face of the housing and has an outer surface made of copper or a copper alloy.

### BACKGROUND OF THE INVENTION

The present invention is drawn to an inductive sensor.

Inductive sensors are used for detecting the position or approach of metallic objects. For example, an inductive sensor can be used as a proximity switch generating a switching signal when an object to be detected reaches a distance threshold with regard to a sensing face of the inductive sensor.

Inductive sensors might be used in harsh environments like in an environment in which welding operations are performed.

U.S. Pat. No. 4,996,408 discloses an electronic proximity switch means adapted to be operated in a non-contact mode for use in a welding zone of a welding means, the electronic proximity switch means including a brass housing, a ceramic disc provided on a responsive-sensitive end face of the switch means, and a coating of anti-stick material provided on a surface of the ceramic disc facing the welding means and on at least a front area of the housing facing the welding means for preventing a formation of a layer of material resulting from a welding operation on the ceramic disc and at least a front area of the housing. Thus, any slag layer formation along the housing might be minimized if not avoided.

The present invention provides an inductive sensor advantageously suited for use in harsh environments such as proximate a welding zone.

### SUMMARY OF THE INVENTION

In accordance with an example embodiment of the present invention, an inductive sensor is provided comprising a housing with at least one sensing face and a sensing unit arranged in the housing. The sensing unit comprises at least one oscillatory circuit with at least one inductive element. The at least one inductive element is arranged proximate to the at least one sensing face of the housing and the sensing face has an outer surface made of copper or a copper alloy. The resonance frequency of the oscillatory circuit may be set to be below approximately 30 kHz.

With the sensing face made at least at the outer surface of copper or a copper alloy, the sticking of welding splatters or of a slag layer to the signal-sensitive portion of the sensor can be avoided in a highly effective manner. Due to the high thermal conductivity of copper a melting on of welding splatters on the surface of the housing at the sensing face is avoided.

Using copper or a copper alloy (at least at its outer surface) for the sensing face is more effective than using, e.g., a Teflon coating, since a Teflon coating must be cleaned from time to time. Also, a sensing face made at least partially of copper or a copper alloy can be manufactured easily. Also, it is easier to manufacture a thread on such a housing made of copper or copper alloy. Further, the signal ratio might be better.

If the resonance frequency of the oscillatory circuit is lowered compared to “conventional” inductive sensors, where the resonance frequency is usually higher than 100 kHz, then, if the copper element or copper alloy element is sufficiently thin, acceptable signals can be achieved.

In particular, the housing may comprise at the at least one sensing face a copper portion made of copper or a copper alloy. Via the copper portion of the housing, the sticking of welding slag or welding splatters can be effectively avoided or at least minimized.

It is possible that the surface made of copper or a copper alloy may be formed by a coating. In one embodiment, the copper portion extends from the outer surface of the housing to an inner surface of the housing. Therefore, a mechanically stable housing element is provided. Also, the inductive sensor can be manufactured in a simple manner.

It is advantageous when the thickness of the copper portion is 0.6 mm or less. In particular, the thickness is 0.5 mm or less. In a preferred embodiment, the thickness of the copper portion is 0.3 mm or less. Therefore, high signal strengths can be achieved despite the copper portion at the sensing face.

Moreover, it is advantageous if the resonance frequency of the at least one oscillatory circuit is set to be below 20 kHz. In particular, the resonance frequency is set to be between 5 kHz and 11 kHz. Therefore, with the appropriate thickness of the copper portion (in particular around 0.3 mm or less) a mechanically advantageous copper portion can be provided with a good signal strength.

It is advantageous if the housing comprises at least one thread. If the housing is made of a metal material and in particular of copper or copper alloy, a thread (in particular an exterior thread) can be formed on the housing for fixing the housing and thereby the conductive sensor at an application.

In one example embodiment, the housing may be completely made of copper or a copper alloy. The housing is completely protected against welding splatters and slag.

In an alternative example embodiment, the housing may be partially made of copper or a copper alloy. In particular, the area at the sensing face of the housing may be made of copper or a copper alloy.

In a further example embodiment, the housing may comprise at least one lid. With the lid, an inner space of the housing is sealed off.

The at least one sensing face may be arranged on the at least one lid. Such, an inductive sensor can be manufactured in a simple manner.

In one example embodiment, the housing may comprise a container part and a separate lid part with the lid part fixed on the housing. Such an inductive sensor can be manufactured in a simple way. The lid part can be fixed after the manufacture of the container part to the container part.

It is advantageous when the at least one lid may be at least partially made of copper or a copper alloy. Therefore, a sensing face is provided on the lid which has a copper surface or a surface made of a copper alloy.

In a further example embodiment, the at least one sensing face may be arranged at a front end of the housing. In such an embodiment, the front end of the housing is protected against welding splatters and welding slag.

In an alternative example embodiment, the at least one sensing face may be arranged on a side of the housing. In such an embodiment, the corresponding side is protected against welding splatters.

It can be provided that the housing comprises at the at least one sensing face at least one plate made of copper or a copper alloy. The plate can be an integral part of the rest of the housing or can be a separate part from the rest of the housing and fixed to the rest of the housing.

The inductive sensor in accordance with the present invention can be advantageously used in an environment in which welding operations are performed. Since the inductive sensor in accordance with the present invention is well-protected against sticking of welding splatters, the inductive sensor in accordance with the present invention has long usage life time.

### BRIEF DESCRIPTION OF THE DRAWINGS

The foregoing and other aspects of the present invention will become more fully understood from the following detailed description of exemplary embodiments in conjunction with the accompanying drawings, in which

FIG. 1 illustrates a first example embodiment of the invention;

FIG. 2 shows a sensing unit in the context of the first example embodiment of the invention;

FIG. 3 illustrates a second example embodiment of the invention;

FIG. 4 illustrates a third example embodiment of the invention; and

FIG. 5 illustrates a sensing unit in the context of the third example embodiment of the invention.

### DETAILED DESCRIPTION OF THE INVENTION

The ensuing detailed description provides exemplary embodiments only, and is not intended to limit the scope, applicability, or configuration of the invention. Rather, the ensuing detailed description of the exemplary embodiments will provide those skilled in the art with an enabling description for implementing an embodiment of the invention. It should be understood that various changes may be made in the function and arrangement of elements without departing from the spirit and scope of the invention as set forth in the appended claims.

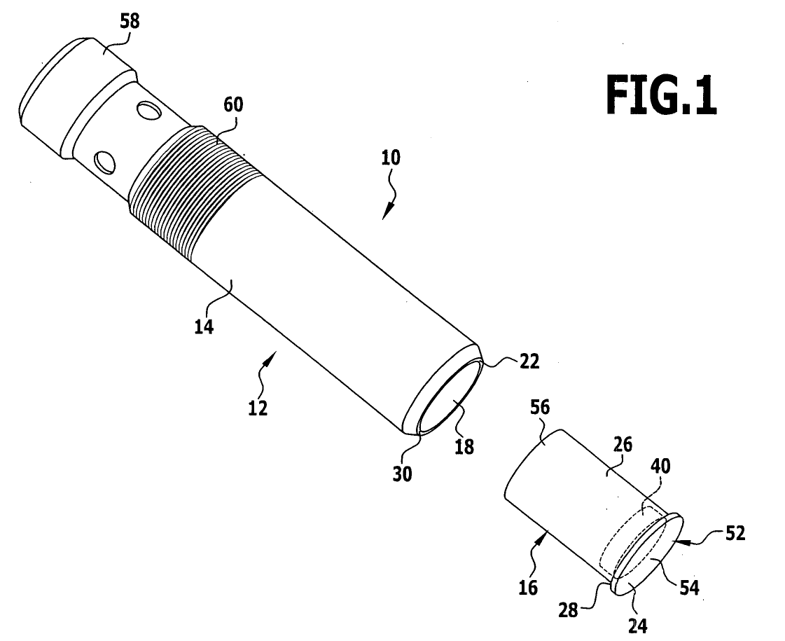

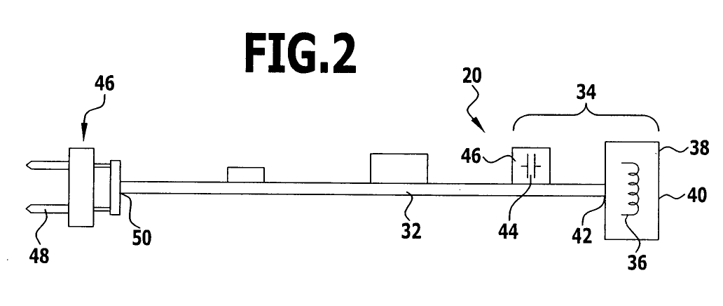

A first example embodiment of an inductive sensor 10 in accordance with the present invention, which is shown in FIG. 1, comprises a housing 12. The housing 12 has a first housing part 14 and a second housing part 16. The first housing part 14 may be a container part with a reception space 18 for a sensing unit 20 (FIG. 2). The second housing part 16 may be a lid part for closing the container part at a front end 22.

The first housing part 14 has, e.g., a cylindrical ring shape with the reception space 18 also being of cylindrical shape.

The second housing part 16 may comprise a lid element 24. In one example embodiment, this lid element 24 is of disc shape. The lid element 24 is connected to an insert part 26 which is, e.g., of a cylindrical ring shape. Via this insert part 26 the lid element 24 is fixed on the first housing part 14. The insert part 26 is positioned in the space inside the first housing part 14.

The insert part 26 has a smaller outer diameter than the lid element 24. Thus, between the insert part 26 and the lid element 24 an annular area 28 is provided at the lid element 24. The first housing part 14 has at its front end 22 an annular end face 30. The annular area 28 may be adapted to rest on the end face 30 without the lid element 24 protruding out of the outer diameter of the first housing part 14.

The sensing unit 20 shown in FIG. 2 comprises in one example embodiment a carrier 32. This carrier 32 may be, e.g., a carrier board on which elements of the sensing unit 20 are arranged.

The sensing unit 20 may comprise (at least one) oscillatory circuit 34. This oscillatory circuit 34 may comprise (at least one) inductive element 36 (coil). This inductive element 36 may be seated on a coil core 38. The coil core 38 and the inductive element 36 form a coil unit 40 which is positioned on the carrier 32.

In particular, the coil unit 40 may be positioned in front of a front end 42 of the carrier 32 and fixed mechanically to the carrier 32. Further, the coil unit 40 may be electrically connected to the carrier 32. For example, the coil unit 40 may be fixed via soldering joints to the carrier 32. The soldering joints may provide the mechanical mounting and the electrical connection.

The oscillatory circuit 34 further may comprise at least one capacitor 44. The at least one capacitor 44 can be realized as a discrete element or as part of an integrated circuit element 46.

The sensing unit 20 may further comprise electronic elements necessary for the detection and evaluation of signals.

In one example embodiment, an electrical connection unit 46 is fixed to the carrier 32. The electrical connection unit 46 may comprise connector pins 48. The electrical connection unit 46 may be fixed to the carrier 32 at an end 50, which is opposite to the front end 42 at which the coil unit 40 is arranged.

The connector pins 48 may be arranged in such a way that they are substantially parallel to the carrier 32.

The sensing unit 20 may be arranged in the housing 12. As shown in FIG. 1 the housing 12 has a sensing face 52 which is defined by the housing portion proximate to the coil unit 40. In the embodiment of FIG. 1, the sensing face 52 is defined by the surface 54 of the lid element 24.

The coil unit 40 may be arranged in an inner space 56 of the insert part 26. Said inner space 56 is surrounded by the wall of the insert part 26.

The connector pins 48 may be at least partially arranged in a connector part 58 of the first housing part 14. The connector pins 48 may protrude out of this connector part 58. The connector part 58 may be seated at an end of the first housing 14 opposite to the front end 22.

The sensing unit 20 may be positioned in the housing 12 encapsulated by a sealing compound. The sealing compound may be introduced into the housing 12 during the manufacture of the inductive sensor 10 when still liquid. After curing, the sealing compound serves to protect the sensing unit 20.

The lid element 24 may be made of copper or a copper alloy. Therefore, the inductive sensor 10 can be used in an environment in which welding operations are performed. During welding, welding splatters may reach the inductive sensor 10. If welding splatters stick to the inductive sensor 10 and in particular to a sensing face, the operation of the inductive sensor 10 can be unreliable.

With the sensing face 52 having a surface of copper or of a copper alloy, welding splatters will substantially not stick to this sensing face 52. Owing to the high thermal conductivity of copper, the surface of the lid element 24 does not melt when hit by a welding splatter. This prevents welding splatters from sticking to the sensing face 52.

The resonance frequency of the oscillatory circuit 34 may be set to be below approximately 30 kHz and in particular below 20 kHz.

Further, the thickness of the lid element 24 may be smaller than 0.6 mm and in particular smaller than 0.5 mm. In one example embodiment, the resonance frequency is 10 kHz and the thickness is 0.3 mm.

The resonance frequency of the oscillatory circuit 34 may be set in such a way that taking into account the thickness of the lid element 24, the sensing signal is not attenuated too much via the copper lid element 24 (which may be made of copper or a copper alloy).

If the thickness of the lid element 24 is smaller, then a higher resonance frequency can be chosen. However, if the thickness of the lid element 24 is too small, the lid element 24 does not provide sufficient mechanical protection. On the other hand, if the thickness of the lid element 24 is larger, then the resonance frequency of the oscillatory circuit 34 may be set lower. However, if the thickness of the lid element 24 is too large, the signal attenuation in the lid element 24 is too high. Accordingly, there exists a range of optimum thickness of the lid element 24 and optimum resonance frequency of the oscillatory circuit 34 in corresponding dependency.

In one example embodiment, the lid element 24 may extend from the sensing face 52 to an inner face (which is directed towards the coil unit 40) and may be made completely of copper or a copper alloy. It could also be provided that only the outer surface of the lid element 24 is made of copper or a copper alloy, whereas the inner face of the lid element 24 is made of another material.

Further, the insert part 26 can be connected in one-piece to the lid element 24 and be manufactured from the same material as the lid element 24. In such an example embodiment, the second housing part 16 may be made of copper or alloy.

Further, the first housing part 14 can be made of copper or a copper alloy or another material.

It is advantageous if the first housing 14 is made of a metallic material. Accordingly, one or more threads 60 and in particular exterior threads can be provided on the housing 12 for fixing the inductive sensor 10 at an application.

In accordance with the present invention, an outer surface of the housing 12 at the sensing face 52 is made of copper or a copper alloy. The housing 12 comprises at the sensing face 52 a copper portion made of copper or copper alloy. Accordingly, the sticking of welding splatters to the inductive sensor 10 is prevented or at least reduced. The housing 12 may be fluid tight and mechanically rugged. With the resonance frequency of the oscillatory circuit 34 set lower than that typically used for known inductive sensors, the copper portion can be “penetrated” by signals.

In comparison to a Teflon coated sensing face, regular cleaning of the sensing face 52 is not necessary.

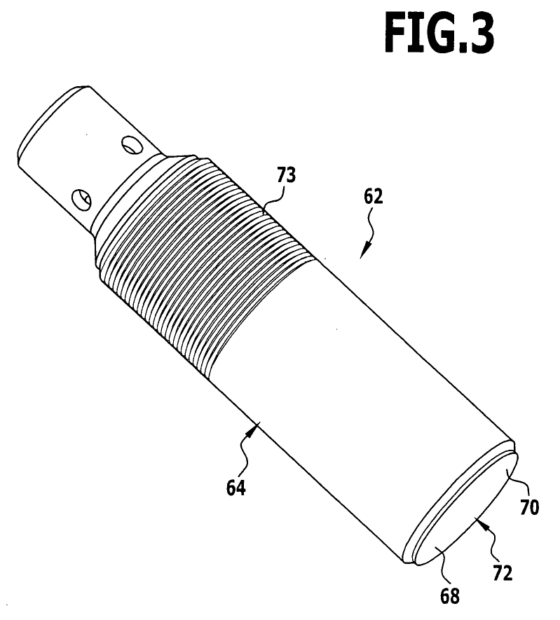

In a second example embodiment, which is shown in FIG. 3, an inductive sensor 62 is provided. The inductive sensor 62 comprises a housing 64 which may be a one-piece housing made of copper or a copper alloy. The housing 64 may be, e.g., of cylindrical design with an inner space. In this inner space a sensing unit 20 is positioned as described above in connection with the example embodiment of FIG. 1.

The housing 64 has a lid 68 which is in a one-piece connection fixed to the rest of the housing 64. The lid 68 may comprise a front face 70 which defines a sensing face 72.

The housing 64 has a thread 73 for fixing the inductive sensor 62 at an application.

The inductive sensor 62 operates as described above in connection with the inductive sensor 10 of FIG. 1.

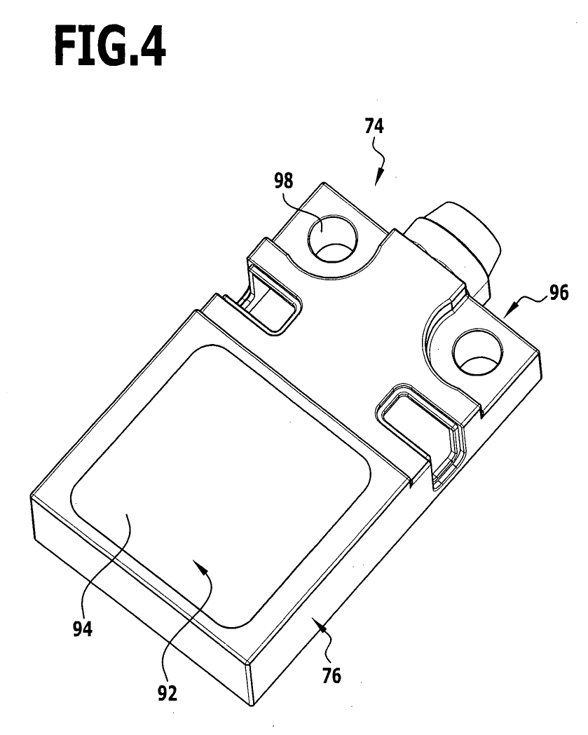

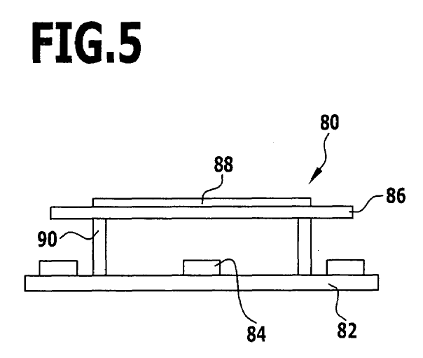

A third example embodiment in accordance with the present invention is shown in FIG. 4. The inductive sensor 74 shown in FIG. 4 may comprise a housing 76 which is generally parallel epiped shaped. The housing 76 may comprise an inner space for accommodating a sensing unit 80 (FIG. 5).

The sensing unit 80 may comprise a first carrier 82 which is in particular a carrier board. On the carrier 82 electronic elements 84 of the sensing unit 80 may be arranged. For example, the carrier 82 may carry an evaluation circuit of the sensing unit 80 and also one or more capacitive elements of an oscillatory circuit.

The sensing unit 80 may further comprise a carrier 86 for one or more inductive elements 88. Such an inductive element 88 may be, for example, a print coil printed on the carrier 86.

The carrier 86 may be arranged in parallel to the carrier 82 at a distance from the carrier 82. For example, the carrier 86 may be supported by arm elements 90 which are fixed to the carrier 82. Accordingly, a compact design of the sensing unit 80 is achieved.

The housing 76 may have a sensing face 92 which is arranged on a side of the housing 76. The sensing face 92 may be proximate to the inductive element 88.

In particular, the inductive element 88 may be proximate to an inner side of the housing 76 at the sensing face 92.

In the embodiment shown in FIG. 4, the sensing face 92 is of rectangular shape. Those skilled in the art will appreciate that the sensing face may take other shapes and forms.

The housing 76 may have at the sensing face 92 a copper portion 94 made of copper or a copper alloy.

In one embodiment, the housing 76 may have a copper plate or a plate made of copper alloy constituting the copper portion 94. This copper plate may be fixed to the rest of the housing 76.

In another embodiment, the housing 76 may be completely made of copper or a copper alloy.

As described above in connection with the inductive sensor 10 and the inductive sensor 62, via the copper portion 94 the sticking of welding splatters to the inductive sensor 74 is avoided. Accordingly, the inductive sensor 74 can be used in an environment in which welding operations are performed.

The inductive sensor 74 may further comprise an attachment portion 96 via which the housing 76 can be fixed to an application. For example, the attachment portion 96 may comprise two or more bores 98 for screwing the housing 76 to an application.

It should now be appreciated that the present invention provides an advantageous inductive element for use in harsh environments such as welding.

Although the invention has been described in connection with various illustrated embodiments, numerous modifications and adaptations may be made thereto without departing from the spirit and scope of the invention as set forth in the claims.

What is claimed is:

1. Inductive sensor, comprising:
a housing with at least one sensing face;
a sensing unit arranged in the housing;
wherein:
the sensing unit comprises at least one oscillatory circuit with at least one inductive element;
the at least one inductive element is arranged proximate to the at least one sensing face of the housing;
the sensing face has an outer surface made of copper or a copper alloy; and
the resonance frequency of the oscillatory circuit is set to be below approximately 30 kHz.

2. Inductive sensor according to claim 1, wherein the housing comprises at the at least one sensing face a copper portion made of copper or a copper alloy.

3. Inductive sensor according to claim 2, wherein the copper portion extends from the outer surface of the housing to an inner surface of the housing.

4. Inductive sensor according to claim 2, wherein a thickness of the copper portion is approximately 0.6 mm or less.

5. Inductive sensor according to claim 2, wherein a thickness of the copper portion is approximately 0.5 mm or less.

6. Inductive sensor according to claim 2, wherein a thickness of the copper portion is approximately 0.3 mm or less.

7. Inductive sensor according to claim 1, wherein a resonance frequency of the at least one oscillatory circuit is set to be below approximately 20 kHz.

8. Inductive sensor according to claim 1, wherein a resonance frequency of the at least one oscillatory circuit is set to be between approximately 5 kHz and 11 kHz.

9. Inductive sensor according to claim 1, wherein the housing comprises at least one thread.

10. Inductive sensor according to claim 1, wherein the housing is completely made of copper or a copper alloy.

11. Inductive sensor according to claim 1, wherein the housing is partially made of copper or a copper alloy.

12. Inductive sensor according to claim 1, wherein the housing comprises at least one lid.

13. Inductive sensor according to claim 12, wherein the at least one sensing face is arranged on the at least one lid.

14. Inductive sensor according to claim 12, wherein the housing comprises a container part and a separate lid part with the lid part fixed on the housing.

15. Inductive sensor according to claim 12, wherein the at least one lid is at least partially made of copper or a copper alloy.

16. Inductive sensor according to claim 1, wherein the at least one sensing face is arranged at a front end of the housing.

17. Inductive sensor according to claim 1, wherein the at least one sensing face is arranged on a side of the housing.

18. Inductive sensor according to claim 1, wherein the housing comprises at the at least one sensing face at least one plate made of copper or a copper alloy.

19. Inductive sensor, comprising:
a housing with at least one sensing face;
a sensing unit arranged in the housing;
wherein;
the sensing unit comprises at least one oscillatory circuit with at least one inductive element;
the at least one inductive element is arranged proximate to the at least one sensing face of the housing;
the housing comprises at the at least one sensing face a copper portion made of copper or a copper alloy; and
the resonance frequency of the oscillatory circuit is set to be below approximately 30 kHz.

20. Method of using an inductive sensor, comprising:
positioning said inductive sensor adjacent a welding application; and
operating said inductive sensor during a welding operation at said welding application;
wherein said inductive sensor comprises:
a housing with at least one sensing face;
a sensing unit arranged in the housing;
the sensing unit comprising at least one oscillatory circuit with at least one inductive element;
the at least one inductive element is arranged proximate to the at least one sensing face of the housing;
the housing comprises at the at least one sensing face a copper portion made of copper or a copper alloy.
